(19) United States
(12) Patent Application Publication
(10) Pub. No.: US 2022/0017804 A1
(43) Pub. Date: Jan. 20, 2022

(54) Composition for Low Dielectric Thermally Conductive Material and Low Dielectric Thermally Conductive Material

(71) Applicant: Kitagawa Industries Co,. Ltd, Inazawa-shi, Aichi (JP)

(72) Inventors: Jianguang Li, Kasugai-shi, Aichi (JP); Masahiro Saito, Kasugai-shi, Aichi (JP); Teruaki Yuoka, Kasugai-shi, Aichi (JP)

(21) Appl. No.: 17/292,382

(22) PCT Filed: Oct. 29, 2019
(86) PCT No.: PCT/JP2019/042383

§ 371 Date: May 7, 2021

(30) Foreign Application Priority Data
Nov. 8, 2018 (JP) 2018-210603

(51) Int. Cl. C09K 5/14; C08L 33/10; C08J 5/18

(52) U.S. Cl. CPC C09K 5/14; C08L 33/10; C08J 5/18; H01L 23/3737; C08J 2333/10; C08J 2435/02; C08L 2203/20

(57) ABSTRACT

A composition for a low dielectric thermally conductive material of the present technology contains: an acrylic resin composition containing an acrylic polymer formed by polymerizing one or two or more types of (meth)acrylates and one or two or more types of (meth)acrylates; crystalline silica having an average particle size of 20 μm or greater; a metal hydroxide having an average particle size of 15 μm or less; a polyfunctional monomer; and a polymerization initiator, wherein per 100 parts by mass of the acrylic resin composition, from 330 parts by mass to 440 parts by mass of the crystalline silica, from 90 parts by mass to 190 parts by mass of the metal hydroxide, from 0.01 parts by mass to 0.5 parts by mass of the polyfunctional monomer, and from 0.6 parts by mass to 1.3 parts by mass of the polymerization initiator are blended.

### TECHNICAL FIELD

The present technology relates to a composition for a low dielectric thermally conductive material and a low dielectric thermally conductive material.

### BACKGROUND ART

When a thermally conductive material is interposed between a heat source (for example, IC) and a heat dissipation plate (heat sink), this becomes a kind of a capacitor. A higher dielectric constant of the thermally conductive material results in a greater electrostatic capacitance of the capacitor, and thus such a capacitor causes generation of high frequency noise depending on the case. Therefore, in the related art, a thermally conductive material with reduced dielectric constant (hereinafter, low dielectric thermally conductive material) has been provided (see, for example, Japan Unexamined Patent Publication No. 2012-119674). In this type of low dielectric thermally conductive material, a hollow filler is added to keep the dielectric constant low. As the hollow filler, for example, a glass balloon, and a fly ash balloon have been used.

Depending on the production method of the low dielectric thermally conductive material, the hollow filler is broken when a resin serving as a base material and the hollow filler are kneaded, and therefore a desired low dielectric constant is not obtained in some cases. Also, the hollow filler is not stably supplied to the market depending on the type thereof, and thus the procurement of the hollow filler has been difficult in some cases.

### SUMMARY

The present technology is to provide a novel low dielectric thermally conductive material that does not use a hollow filler. That is, the present technology provides:

<1> A composition for a low dielectric thermally conductive material, containing: an acrylic resin composition containing an acrylic polymer formed by polymerizing one or two or more types of (meth)acrylates and one or two or more types of (meth)acrylates; crystalline silica having an average particle size of 20 μm or greater; a metal hydroxide having an average particle size of 15 μm or less; a polyfunctional monomer; and a polymerization initiator, wherein per 100 parts by mass of the acrylic resin composition, from 330 parts by mass to 440 parts by mass of the crystalline silica, from 90 parts by mass to 190 parts by mass of the metal hydroxide, from 0.01 parts by mass to 0.5 parts by mass of the polyfunctional monomer, and from 0.6 parts by mass to 1.3 parts by mass of the polymerization initiator are blended.
<2> The composition for a low dielectric thermally conductive material according to <1>, wherein the metal hydroxide is composed of aluminum hydroxide.
<3> A low dielectric thermally conductive material containing a cured product of the composition for a low dielectric thermally conductive material according to <1> or <2>.
<4> The low dielectric thermally conductive material according to <3>, wherein an asker C hardness is 50 or less, a relative dielectric constant is 5.0 or less, and a thermal conductivity is 1.4 W/m·K or greater.
<5> The low dielectric thermally conductive material according to <3> or <4>, wherein the low dielectric thermally conductive material is composed of the cured product of the composition for a low dielectric thermally conductive material formed in a sheet shape.

According to the present technology, a novel low dielectric thermally conductive material that does not use a hollow filler, and the like can be provided.

### DETAILED DESCRIPTION

The composition for a low dielectric thermally conductive material of the present embodiment is a composition for producing a low dielectric thermally conductive material, and is liquid (syrup) having fluidity under room temperature (23° C.) condition. The composition for a low dielectric thermally conductive material mainly contains an acrylic resin composition, a polyfunctional monomer, crystalline silica, a metal hydroxide, and a polymerization initiator.

The acrylic resin composition is a composition containing at least an acrylic polymer formed by polymerizing one or two or more types of (meth)acrylates and one or two or more types of (meth)acrylates. Also, the acrylic resin composition may further contain an aromatic ester. Note that in the present specification, “(meth)acrylate” means “methacrylate and/or acrylate” (either or both of acrylate and methacrylate).

The acrylic polymer is an acrylic polymer obtained by polymerizing(meth)acrylate having a straight-chain or branched-chain alkyl group having from 2 to 18 carbon atoms (hereinafter, may be referred to as alkyl(meth)acrylate) alone or in combination of two or more types thereof. Examples of the alkyl(meth)acrylate include ethyl (meth)acrylate, n-propyl (meth)acrylate, i-propyl (meth)acrylate, n-butyl (meth)acrylate, i-butyl (meth)acrylate, n-pentyl (meth)acrylate, i-pentyl (meth)acrylate, 2-ethylhexyl (meta) acrylate, n-hexyl (meth)acrylate, octyl (meth)acrylate, i-octyl (meth)acrylate, nonyl (meth)acrylate, i-nonyl (meth)acrylate, i-decyl (meth)acrylate, lauryl (meth)acrylate, tridecyl (meth)acrylate, i-myristyl (meth)acrylate, stearyl (meth)acrylate, and i-stearyl (meth)acrylate.

The acrylic resin composition contains (meth)acrylate, which is a monomer, together with the acrylic polymer. The (meth)acrylate as a monomer may be the (meth)acrylates given as an example of the material of the above acrylic polymer (that is, alkyl(meth)acrylate) alone or in combination of two or more types thereof, or may be (meth)acrylate other than alkyl(meth)acrylate. The monomer has a polymerizable functional group containing a carbon-carbon double bond.

The acrylic resin composition may contain another copolymerizable monomer other than the acrylic polymer and the (meth)acrylate as a monomer. Examples of the other copolymerizable monomer include copolymerizable vinyl monomers having a vinyl group (for example, acryl amide, acrylonitrile, methyl vinyl ether, ethyl vinyl ether, vinylacetate, and vinyl chloride), and aromatic (meth)acrylates (for example, phenyl (meth)acrylate, halogen-substituted phenyl (meth)acrylate, benzyl (meth)acrylate, 2-phenoxyethyl (meth)acrylate, and 2-phenylethyl (meth)acrylate). These may be used alone or in combination of two or more types thereof.

The content (mass %) of the acrylic polymer in the acrylic resin composition is, for example, preferably 10 mass % or greater, more preferably 15 mass % or greater, preferably 30 mass % or less, and more preferably 25 mass % or less. Also, the content (mass %) of the (meth)acrylate in the acrylic resin composition is, for example, preferably 40 mass % or greater, more preferably 45 mass % or greater, preferably 60 mass % or less, and more preferably 55 mass % or greater. Also, the content (mass %) of the aromatic ester in the acrylic resin composition is, for example, preferably 20 mass % or greater, more preferably 25 mass % or greater, preferably 40 mass % or less, and more preferably 35 mass % or less.

As the acrylic resin composition, commercially available products (for example, ACRYCURE (registered trademark) HD-A series, available from Nippon Shokubai Co., Ltd.) may be used.

When the above acrylic resin composition is used as a base material of the low dielectric thermally conductive material, the hardness of the low dielectric thermally conductive material can be set to a desired low value.

The polyfunctional monomer is composed of a monomer having two or more (meth)acryloyl groups in the molecule. Example of the bifunctional (meth)acrylate monomer having two (meth)acryloyl groups in the molecule include 1,3-butylene glycol di(meth)acrylate, 1,4-butanediol di(meth)acrylate, 1,6-hexanediol di(meth)acrylate, 1,9-nonandiol di(meth)acrylate, neopentyl glycol di(meth)acrylate, dicyclopentanyl di(meth)acrylate, 2-ethyl-2-butyl-propanediol (meth)acrylate, neopentylglycol-modified trimethylolpropane di(meth)acrylate, stearic acid-modified pentaerythritol diacrylate, polypropylene glycol di(meth)acrylate, 2,2-bis[4-(meth)acryloxy-diethoxyphenyl]propane, 2,2-bis[4-(meth)acryloxy-propoxyphenyl]propane, and 2,2-bis[4-(meth)acryloxy-tetraethoxyphenyl]propane.

Examples of the trifunctional (meth)acrylate monomer include trimethylol propane tri(meth)acrylate, and tris[(meth)acryloxyethyl]isocyanurate. Examples of the tetra- or higher functional (meth)acrylate monomer include dimethylolpropane tetra(meth)arylate, pentaerythritol tetra(meth)acrylate, pentaerythritol ethoxytetra(meth)acrylate, dipentaerythritol penta(meth)acrylate, and dipentaerythritol hexa(meth)acrylate.

The polyfunctional monomer may be used alone or in combination of two or more types thereof. Among these polyfunctional monomers, 1,6-hexanediol di(meth)acrylate and the like are preferable.

In the composition for a low dielectric thermally conductive material, 0.01 parts by mass or greater, preferably 0.03 parts by mass or greater, 0.5 parts by mass or less, preferably 0.3 parts by mass or less, and more preferably 0.1 parts by mass or less of the polyfunctional monomer is blended per 100 parts by mass of the acrylic resin composition. When the composition for a low dielectric thermally conductive material contains the polyfunctional monomer in the above proportions, the hardness of the low dielectric thermally conductive material produced from the composition for a low dielectric thermally conductive material can be set to a desired low value.

The polymerization initiator is formed from peroxide, and when being heated to a predetermined temperature or higher, generates radicals. Examples of the polymerization initiator include organic peroxides such as di-(4-t-butylcyclohexyl)peroxydicarbonate, lauroyl peroxide, t-amylperoxy-2-ethylhexanoate, benzoyl peroxide, t-butylperoxy-2-ethylhexanoate, and 4-(1,1-dimethylethyl)cyclohexanol. Among the polymerization initiators, di-(4-t-butylcyclohexyl)peroxydicarbonate is preferable. These polymerization initiators may be used alone or in combination of two or more types thereof.

In the composition for a low dielectric thermally conductive material, 0.6 parts by mass or greater, preferably 0.7 parts by mass or greater, 1.3 parts by mass or less, and preferably 1.2 parts by mass or less of the polymerization initiator is blended per 100 parts by mass of the acrylic resin composition. When the composition for a low dielectric thermally conductive material contains the polymerization initiator in the above proportions, the hardness of the low dielectric thermally conductive material produced from the composition for a low dielectric thermally conductive material can be set to a desired low value.

The crystalline silica has a particulate shape and is used for increasing the thermal conductivity of the low dielectric thermally conductive material and decreasing the dielectric constant. The average particle size of the crystalline silica (lower limit value) is 20 μm or greater, preferably 25 μm or greater, and more preferably 30 μm or greater. The upper limit value of the average particle size of the crystalline silica is not particularly limited as long as the present technology is not impaired. The upper limit value is, for example, preferably 50 μm or less and more preferably 40 μm or less. When the average particle size of the crystalline silica is within such a range, the thermal conductivity of the low dielectric thermally conductive material produced from the composition for a low dielectric thermally conductive material can be set to a desired high value, and further, the dielectric constant (relative dielectric constant) can be set to a desired low value.

Incidentally, the average particle size of the filler such as crystalline silica in the present specification is a volume-based average particle size (D50) determined by a laser diffraction method. The average particle size can be measured by a laser diffraction particle size distribution analyzer.

Also, the thermal conductivity of the crystalline silica is not particularly limited as long as the present technology is not impaired. The thermal conductivity is, for example, preferably 7 W/m·K or greater and more preferably 10 W/m·K or greater.

Also, the relative dielectric constant of the crystalline silica is not particularly limited as long as the present technology is not impaired. The relative dielectric constant is, for example, preferably 4.0 or less and more preferably 3.9 or less.

Also, the specific gravity of the crystalline silica is not particularly limited as long as the present technology is not impaired. The specific gravity is, for example, preferably 2.5 or greater and more preferably 2.6 or greater.

In the composition for a low dielectric thermally conductive material, 330 parts by mass or greater, preferably 340 parts by mass or greater, more preferably 350 parts by mass or greater, 440 parts by mass or less, preferably 430 parts by mass or less, and more preferably 420 parts by mass or less of the crystalline silica is blended per 100 parts by mass of the acrylic resin composition. When the composition for a low dielectric thermally conductive material contains the crystalline silica in the above proportions, the thermal conductivity of the low dielectric thermally conductive material produced from the composition for a low dielectric thermally conductive material can be set to a desired high value, and further, the dielectric constant (relative dielectric constant) can be set to a desired low value. Further, when the composition for a low dielectric thermally conductive material contains the crystalline silica in the above proportions, precipitation of the filler such as crystalline silica is suppressed, resulting in longer pot life and excellent storage properties. Moreover, such a composition has an appropriate fluidity (viscosity) which enables coating.

It is not preferable to use molten silica for the low dielectric thermally conductive material because the molten silica has a lower thermal conductivity than that of the crystalline silica, for example.

The metal hydroxide has a particulate shape (substantially spherical shape) and is used for ensuring the moisture resistance, flame retardancy, and the like of the low dielectric thermally conductive material. The metal hydroxide is not particularly limited as long as the present technology is not impaired, but, for example, aluminum hydroxide is preferable.

The average particle size of the metal hydroxide (upper limit value) is 15 μm or less, preferably 13 μm or less, and more preferably 12 μm or less. The lower limit value of the average particle size of the metal hydroxide is not particularly limited as long as the present technology is not impaired. The lower limit value is, for example, preferably 5 μm or greater and more preferably 7 μm or greater.

In a case where aluminum hydroxide is used as a metal hydroxide, the aluminum hydroxide is preferably low soda aluminum hydroxide having an amount of soluble sodium of less than 100 ppm. In the present specification, the amount of soluble sodium is the amount of sodium ions (Nat) dissolved in water when low soda aluminum hydroxide and water are brought into contact.

In the composition for a low dielectric thermally conductive material, 90 parts by mass or greater, preferably 100 parts by mass or greater, more preferably 110 parts by mass or greater, 190 parts by mass or less, preferably 180 parts by mass or less, and more preferably 170 parts by mass or less of the metal hydroxide is blended per 100 parts by mass of the acrylic resin composition.

When the composition for a low dielectric thermally conductive material contains the metal hydroxide (for example, aluminum hydroxide) in the above proportions, the resistance (non-water absorbency), flame retardancy, and the like of the low dielectric thermally conductive material are ensured. Further, when the composition for a low dielectric thermally conductive material contains the metal hydroxide in the above proportions, precipitation of the filler such as metal hydroxide is suppressed, resulting in longer pot life and excellent storage properties. Moreover, such a composition has an appropriate fluidity (viscosity) which enables coating.

The composition for a low dielectric thermally conductive material may further contain other components as long as the present technology is not impaired. Examples of the other component include an antioxidant, a thickener, a coloring agent (pigment, dye, for example), a plasticizer, a flame retardant, a preservative, and a solvent.

As the antioxidant, for example, a phenol-based antioxidant which has radical capturing effect can be used. When such an antioxidant is blended, polymerization reaction of the acrylic resin during production of the low dielectric thermally conductive material can be suppressed (controlled), and thus the hardness of the low dielectric thermally conductive material can be easily controlled to a desired low value.

In the composition for a low dielectric thermally conductive material, for example, preferably 0.6 parts by mass or greater, more preferably 0.7 parts by mass or greater, preferably 1.3 parts by mass or less, and more preferably 1.2 parts by mass or less of the antioxidant may be blended per 100 parts by mass of the acrylic resin composition. The antioxidant may be blended in the same proportion (same amount) as that of the polymerization initiator.

The thickener has a particulate shape and may be blended when the viscosity (fluidity) of the composition for a low dielectric thermally conductive material is adjusted to an appropriate level. The thickener is not particularly limited as long as the present technology is not impaired, but, for example, a high-density hydrophobic fumed silica is used. Note that the high-density hydrophobic fumed silica may be subjected to surface treatment with dimethyldichlorosilane or the like. The average particle size of the thickener (upper limit value) is not particularly limited as long as the present technology is not impaired. The upper limit value is, for example, preferably 50 nm or less, more preferably 30 nm or less, and particularly preferably 20 nm or less. Also, the lower limit value of the average particle size of the thickener is not particularly limited as long as the present technology is not impaired. The lower limit value is, for example, preferably 1 nm or greater and preferably 5 nm or greater.

In the composition for a low dielectric thermally conductive material, for example, preferably 10 parts by mass or less, more preferably 5 parts by mass or less, and even more preferably 3 parts by mass or less of the thickener may be blended per 100 parts by mass of the acrylic resin composition.

The plasticizer is blended as necessary for the purpose of, for example, adjusting the hardness of the low dielectric thermally conductive material to a desired low value. The plasticizer is not particularly limited as long as the present technology is not impaired, but, for example, a trimellitate ester plasticizer may be used.

In the composition for a low dielectric thermally conductive material, preferably 4 parts by mass or less, and more preferably 3.5 parts by mass or less of the plasticizer may be blended per 100 parts by mass of the acrylic resin composition.

The method of producing the low dielectric thermally conductive material of the present embodiment is a method of producing a low dielectric thermally conductive material by utilizing the above composition for a low dielectric thermally conductive material. The method of producing a low dielectric thermally conductive material includes a coating step of coating a surface of a support substrate with a composition for a low dielectric thermally conductive material to form a coating layer formed from the composition for a low dielectric thermally conductive material; and a heating step of heating the coating layer to cure the coating layer, thus obtaining a low dielectric thermally conductive material formed from a cured product of the coating layer.

In the coating step, the composition for a low dielectric thermally conductive material is coated onto a predetermined support substrate by utilizing a known coating method (for example, a coating method utilizing a coater or the like). The support substrate is formed from, for example, a plastic film such as polyethylene terephthalate. A coating layer of the composition for a low dielectric thermally conductive material is formed on the surface of the support substrate. Note that peeling treatment may be performed on the surface of the support substrate so that the cured product of the coating layer is easily peeled off finally.

The thickness of the coating layer of the composition for a low dielectric thermally conductive material formed on the support substrate is not particularly limited, and is appropriately set according to the purpose.

Also, the support substrate is finally peeled at the time of using the low dielectric thermally conductive material, and may be disposed on one surface or both surfaces of the coating layer formed from the composition for a low dielectric thermally conductive material in the production step of the low hardness damping material.

Here, the coating step using a coater will be described. The coater includes a pair of rolls disposed facing to each other in the vertical direction at a predetermined interval, and a hopper whose lower end opens toward the pair of rolls. Also, a plastic film is wound around each of the pair of rolls, and along with rotation of these rolls, a pair of the plastic films are sent toward the same direction (direction opposite to the hopper) at a predetermined distance.

A composition for a low dielectric thermally conductive material prepared in advance is extruded between the pair of plastic films, and a sheet-shaped coating layer is formed. Incidentally, as described below, the sheet-shaped coating layer sandwiched between the pair of plastic films is cured by heating in the heating step.

In the heating step, the coating layer formed on the support substrate is heated to a temperature equal to or higher than the curing temperature of the composition for a low dielectric thermally conductive material, and curing reaction proceeds in the composition for a low dielectric thermally conductive material forming the coating layer. In the heating step, radicals are generated from the polymerization initiator (peroxide) in the composition for a low dielectric thermally conductive material, and polymerization reaction proceeds in the composition for a low dielectric thermally conductive material, and thereby the coating layer is cured.

In the heating step, a known heating device such as a heater is utilized. For example, the heating device (heater) is placed on the downstream side of the coater and the sheet-shaped coating layer sandwiched between the pair of plastic films is cured by heating with a heating device.

When the coating layer is cured by heating in this way, a low dielectric thermally conductive material formed from a cured product of the coating layer can be obtained. Note that the shape of the low dielectric thermally conductive material may be a sheet shape or another shape.

The low dielectric thermally conductive material of the present embodiment has low dielectric constant (relative dielectric constant), specifically, a dielectric constant of 5.0 or less, and can suppress generation of high frequency noise due to inductive coupling. The measurement method of the dielectric constant (relative dielectric constant) will be described below.

Further, the low dielectric thermally conductive material has high thermal conductivity, specifically, a thermal conductivity of 1.4 W/m·K or greater, and thus has excellent thermal conductivity. The measurement method of the thermal conductivity will be described below. Further, the low dielectric thermally conductive material has an asker C hardness of 50 or less, and thus has an appropriate hardness (flexibility). Further, the low dielectric thermally conductive material is excellent in flame retardancy, moisture resistance, processability, adhesion to an adherend, and the like.

As described above, in the present embodiment, a low dielectric thermally conductive material having low dielectric constant and having excellent thermal conductivity, flame retardancy, moisture resistance, and the like can be obtained by using, for example, a predetermined crystalline silica without using a hollow filler such as a glass balloon and a fly ash balloon.

The low dielectric thermally conductive material of the present embodiment is interposed between a heat source (for example, IC) and a heat dissipation plate (for example, heat sink), and utilized for transmitting heat from the heat source to the heat dissipation plate. Also, the low dielectric thermally conductive material of the present embodiment suppresses generation of high frequency noise, and thus can reduce data transmission loss in a large capacity and high frequency band in optical communication, or electronic devices and office automation equipment.

### EXAMPLES

Hereinafter, the present technology will be described in more detail based on examples. Note that the present technology is not limited to these examples.

[Preparation of Composition for Low Dielectric Thermally Conductive Material]

### Examples 1 to 6

Crystalline silica, aluminum hydroxide, a thickener, a coloring agent, a plasticizer, a polyfunctional monomer, a polymerization initiator, and an antioxidant were added to 100 parts by mass of an acrylic resin composition in the blended amounts (parts by mass) shown in Tables 1 and 2, and mixed, to obtain each of the compositions for low dielectric thermally conductive material of Examples 1 to 6. Details of each component are as follows.

“Acrylic resin composition”: trade name “ACRYCURE (registered trademark) HDA218” (available from Nippon Shokubai Co., Ltd., composition containing a (meth)acrylic acid ester-based polymer, acrylic acid 2-ethyl hexyl, and an aromatic ester)

“Crystalline silica”: trade name “S” (available from Fumitec Corporation, crystalline silica powder, average particle size: 31.4 μm)
“Aluminum hydroxide”: trade name “BF083” (available from Nippon Light Metal Company, Ltd., low soda aluminum hydroxide, average particle size: 10 μm)
“Thickener”: trade name “AEROSIL (registered trademark) R972 CF” (available from Nippon Aerosil Co. Ltd., high-density hydrophobic fumed silica (surface treated with dimethyldichlorosilane), average particle size: 16 nm)
“Coloring agent”: trade name “Daiichi violet DV-10” (available from Daiichi Kasei Co., Ltd., Pigment Violet 15, pigment: violet)
“Plasticizer”: trade name “ADK CIZER” (registered trademark) C-880″ (available from Adeka Corporation, trimellitate ester plasticizer, viscosity: 100 mPa·s (25° C.))
“Polyfunctional monomer”: trade name “LIGHT ACRYLATE (registered trademark) 1.6HX-A” (available from Kyoeisha Chemical Co., Ltd., 1,6-hexanediol diacrylate)
“Polymerization initiator”: trade name “PERKADOX (registered trademark) 16” (available from Kayaku Akzo Corporation, di-(4-tert-butylcyclohexyl)peroxydicarbonate, 4-(1,1-dimethylethyl)cyclohexanol)
“Antioxidant”: trade name “ADK STAB” (registered trademark) AO-60″ (available from Adeka Corporation, tetrakis[methylene-3-(3′,5′-di-t-butyl-4′-hydroxyphenyl) propionate]methane)

### Comparative Examples 1 to 11

The compositions of Comparative Examples 1 to 11 were obtained in the same manner as in Example 1 except for changing the blended amount of each component (parts by mass) to the amount shown in Tables 1 and 2.

### Comparative Example 12

The composition of Comparative Example 12 was obtained in the same manner as in Example 1 except for changing the blended amount of each component (parts by mass) to the amount shown in Table 3.

### Comparative Example 13

The composition of Comparative Example 13 was obtained in the same manner as in Example 1 except for using, as crystalline silica, trade name “R” (available from Fumitec Corporation, crystalline silica powder, average particle size: 3.9 μm) and changing the blended amount of each component (parts by mass) to the amount shown in Table 3.

[Production of Low Dielectric Thermally Conductive Material]

### Examples 1 to 6

Each of the compositions for a low dielectric thermally conductive material of Examples 1 to 6 was applied onto the surface of a PET substrate subjected to peeling treatment by using a coating machine (coater), to form a coating layer of each composition for a low dielectric thermally conductive material, and then each coating layer was heated at 90° C. for 5 minute. Thus, a sheet formed from each of the compositions for a low dielectric thermally conductive material of Examples 1 to 6 (an example of the low dielectric thermally conductive material, thickness: 1 mm) was obtained.

### Comparative Examples 1 to 13

A sheet was produced by using each of the compositions of Comparative Examples 1 to 13 in the same manner as in Example 1.

Note that, for the compositions of Comparative Example 1 and Comparative Example 4, the resin component and the filler such as crystalline silica were separated, and thus a sheet could not be formed. The composition of Comparative Example 3, which had low fluidity and was hard, could not be applied to the surface of the PET base material, and thus a sheet could not be obtained.

[Evaluation]

### (Processability and Properties)

For the composition of each of Examples and Comparative Examples, “whether separation occurs”, and “whether it has fluidity (viscosity) that enables to coat by a coating machine” and “whether aggregation of the filler occurs” were confirmed. Further, for the sheet of each of Examples and Comparative Examples, “whether the appearance has a problem” and the like were confirmed. A case where there is no these problems was indicated as “Good”. The results were shown in Tables 1 to 3.

(Hardness)

The hardness of the sheet of each of Examples and Comparative Examples was measured by using a constant loader for a durometer (available from Elastron, Inc.) and an Asker Durometer Type C in accordance with JIS K7312. Specifically, the indenter point of the durometer was brought into contact with a test piece cut out from the sheet of each of Examples and Comparative Examples, and a value 30 seconds after a state in which the entire load was applied was read. The results were shown in Tables 1 to 3. A case where the asker Durometer Type C is 50 or less can be said to have a preferable hardness (softness).

(Thermal Conductivity)

The thermal conductivity (W/m·K) was measured for the sheet of each of Examples and Comparative Examples by utilizing a hot disc method (ISO/CD 22007-2). The results were shown in Tables 1 to 3. A case where the thermal conductivity is 1.4 W/m·K or greater can be said to have a preferable thermal conductivity.

(Relative Dielectric Constant)

The relative dielectric constant was determined for the sheet of each of Examples and Comparative Examples in accordance with JIS C2138 (frequency: 100 MHz). The results were shown in Tables 1 to 3. A case where the relative dielectric constant is 5.0 or less can be said to be preferable in terms of suppressing high frequency noise.

(Flame Retardancy)

In each of Examples and Comparative examples, a test piece having a predetermined size (125 mm in length×13 mm in width×1 mm in thickness) was cut out from the obtained sheet, and the test piece was subjected to a vertical flame test in accordance with the UL94V standard. The results were shown in Tables 1 to 3. When the result of flame retardancy is “V-0”, it can be said to be preferable.

(Moisture Resistance)

The evaluation sample of each of Examples and Comparative examples was left to stand in a thermo-hygrostat set at 85° C. and 85% RH for 250 hours. Then, the evaluation sample was taken out from the thermo-hygrostat, and the relative dielectric constant thereof was measured. A case where increase in the relative dielectric constant is 0.6 or less compared to that before the evaluation sample is placed in a thermo-hygrostat was determined to have moisture resistance (“Good”) and a case where increase in the relative dielectric constant is greater than 0.6 was determined to have no moisture resistance (“Poor”). The results were shown in Tables 1 to 3.

TABLE 1

| | | | Example | Example | Comparative |
|---|---|---|---|---|---|
| | | Product name | 1 | 2 | Example 1 |
| Composition | Acrylic resin composition | HD-A218 | 100 | 100 | 100 |
| | Crystalline silica (31.4 μm) | S | 365 | 406 | 284 |
| | Aluminum hydroxide (10 μm) | BF083 | 122 | 122 | 122 |
| | Thickener (16 nm) | R972CF | 1.5 | 1.5 | 1.5 |
| | Coloring agent | DV-10 | 2 | 2 | 2 |
| | Plasticizer | C-880 | 3 | 3 | 3 |
| | Polyfunctional monomer | 1.6HX-A | 0.05 | 0.05 | 0.05 |
| | Polymerization initiator | PERKADOX 16 | 1 | 1 | 1 |
| | Antioxidant | AO-60 | 1 | 1 | 1 |

| | | | | |
|---|---|---|---|---|
| Evaluation | Processability and properties | Good | Good | Separated |
| | Hardness (asker C) | 38 | 40 | — |
| | Thermal conductivity (W/m · K) | 1.61 | 1.63 | — |
| | Relative dielectric Constant | 4.60 | 4.63 | — |
| | Flame retardancy (UL94 test) | V-0 | V-0 | — |
| | Moisture resistance | Good | Good | — |

| | | | Comparative | Comparative | Example |
|---|---|---|---|---|---|
| | | Product name | Example 2 | Example 3 | 3 |
| Composition | Acrylic resin composition | HD-A218 | 100 | 100 | 100 |
| | Crystalline silica (31.4 μm) | S | 325 | 446 | 365 |
| | Aluminum hydroxide (10 μm) | BF083 | 122 | 122 | 162 |
| | Thickener (16 nm) | R972CF | 1.5 | 1.5 | 1.5 |
| | Coloring agent | DV-10 | 2 | 2 | 2 |
| | Plasticizer | C-880 | 3 | 3 | 3 |
| | Polyfunctional monomer | 1.6HX-A | 0.05 | 0.05 | 0.05 |
| | Polymerization initiator | PERKADOX 16 | 1 | 1 | 1 |
| | Antioxidant | AO-60 | 1 | 1 | 1 |

| | | | | |
|---|---|---|---|---|
| Evaluation | Processability and properties | Separated in | Fluidity low | Good |
| | | small amount | | |
| | Hardness (asker C) | 35 | — | 40 |
| | Thermal conductivity (W/m · K) | 1.51 | — | 1.65 |
| | Relative dielectric Constant | 4.62 | — | 4.67 |
| | Flame retardancy (UL94 test) | V-0 | — | V-0 |
| | Moisture resistance | Good | — | Good |

| | | Product | Comparative | Comparative | Comparative |
|---|---|---|---|---|---|
| | | name | Example 4 | Example 5 | Example 6 |
| Composition | Acrylic resin composition | HD-A218 | 100 | 100 | 100 |
| | Crystalline silica (31.4 μm) | S | 365 | 365 | 365 |
| | Aluminum hydroxide (10 μm) | BF083 | 41 | 81 | 203 |
| | Thickener (16 nm) | R972CF | 1.5 | 1.5 | 1.5 |
| | Coloring agent | DV-10 | 2 | 2 | 2 |
| | Plasticizer | C-880 | 3 | 3 | 3 |
| | Polyfunctional monomer | 1.6HX-A | 0.05 | 0.05 | 0.05 |
| | Polymerization initiator | PERKADOX 16 | 1 | 1 | 1 |
| | Antioxidant | AO-60 | 1 | 1 | 1 |

| | | | | |
|---|---|---|---|---|
| Evaluation | Processability and properties | Separated | Separated in | Fluidity |
| | | | small amount | slightly low |
| | Hardness (asker C) | — | 35 | 51 |
| | Thermal conductivity (W/m · K) | — | 1.52 | 1.70 |
| | Relative dielectric Constant | — | 4.51 | 4.83 |
| | Flame retardancy (UL94 test) | — | V-2 | V-0 |
| | Moisture resistance | — | Good | Good |

TABLE 2

| | | Product | Example | Comparative | Comparative |
|---|---|---|---|---|---|
| | | name | 4 | Example 7 | Example 8 |
| Composition | Acrylic resin composition | HD-A218 | 100 | 100 | 100 |
| | Crystalline silica (31.4 μm) | S | 365 | 365 | 365 |
| | Aluminum hydroxide (10 μm) | BF083 | 122 | 122 | 122 |
| | Thickener (16 nm) | R972CF | 1.5 | 1.5 | 1.5 |
| | Coloring agent | DV-10 | 2 | 2 | 2 |
| | Plasticizer | C-880 | 3 | 3 | 3 |
| | Polyfunctional monomer | 1.6HX-A | 0.05 | 0.05 | 0.05 |
| | Polymerization initiator | PERKADOX 16 | 0.75 | 0.5 | 1.5 |
| | Antioxidant | AO-60 | 1 | 1 | 1 |

| | | | | |
|---|---|---|---|---|
| Evaluation | Processability and properties | Good | Material | Good |
| | | | attached | |
| | Hardness (asker C) | 42 | 40 | 57 |
| | Thermal conductivity (W/m · K) | 1.54 | 1.53 | 1.62 |
| | Relative dielectric constant | 4.51 | 4.50 | 4.53 |
| | Flame retardancy (UL94 test) | V-0 | V-0 | V-0 |
| | Moisture resistance | Good | Good | Good |

| | | Product | Comparative | Example | Example |
|---|---|---|---|---|---|
| | | name | Example 9 | 5 | 6 |
| Composition | Acrylic resin composition | HD-A218 | 100 | 100 | 100 |
| | Crystalline silica (31.4 μm) | S | 365 | 365 | 365 |
| | Aluminum hydroxide (10 μm) | BF083 | 122 | 122 | 122 |
| | Thickener (16 nm) | R972CF | 1.5 | 1.5 | 1.5 |
| | Coloring agent | DV-10 | 2 | 2 | 2 |
| | Plasticizer | C-880 | 3 | 1.8 | 0 |
| | Polyfunctional monomer | 1.6HX-A | 0.05 | 0.05 | 0.05 |
| | Polymerization initiator | PERKADOX 16 | 2 | 1 | 1 |
| | Antioxidant | AO-60 | 1 | 1 | 1 |

| | | | | |
|---|---|---|---|---|
| Evaluation | Processability and properties | Good | Good | Good |
| | Hardness (asker C) | 60 | 40 | 42 |
| | Thermal conductivity (W/m · K) | 1.65 | 1.61 | 1.62 |
| | Relative dielectric constant | 4.58 | 4.59 | 4.64 |
| | Flame retardancy (UL94 test) | V-0 | V-0 | V-0 |
| | Moisture resistance | Good | Good | Good |

| | | | Comparative | Comparative |
|---|---|---|---|---|
| | | Product name | Example 10 | Example 11 |
| Composition | Acrylic resin composition | HD-A218 | 100 | 100 |
| | Crystalline silica (31.4 μm) | S | 365 | 365 |
| | Aluminum hydroxide (10 μm) | BF083 | 122 | 122 |
| | Thickener (16 nm) | R972CF | 1.5 | 1.5 |
| | Coloring agent | DV-10 | 2 | 2 |
| | Plasticizer | C-880 | 4.2 | 6 |
| | Polyfunctional monomer | 1.6HX-A | 0.05 | 0.05 |
| | Polymerization initiator | PERKADOX 16 | 1 | 1 |
| | Antioxidant | AO-60 | 1 | 1 |

| | | | |
|---|---|---|---|
| Evaluation | Processability and properties | Sheet slightly | Sheet |
| | | deformed | deformed |
| | Hardness (asker C) | 37 | 36 |
| | Thermal conductivity (W/m · K) | 1.56 | 1.55 |
| | Relative dielectric constant | 4.61 | 4.82 |
| | Flame retardancy (UL94 test) | V-0 | V-0 |
| | Moisture resistance | Good | Good |

TABLE 3

| | | | Comparative | Comparative |
|---|---|---|---|---|
| | | Product name | Example 12 | Example 13 |
| Composition | Acrylic resin composition | HD-A218 | 100 | 100 |
| | Crystalline silica (31.4 μm) | S | 406 | |
| | Crystalline silica (3.9 μm) | R | | 406 |
| | Aluminum hydroxide (10 μm) | BF083 | | |
| | Thickener (16 nm) | R972 CF | | |
| | Coloring agent | DV-10 | | |
| | Plasticizer | C-880 | | |
| | Polyfunctional monomer | 1.6HX-A | 0.05 | 0.05 |
| | Polymerization initiator | PERKADOX 16 | 0.5 | 0.5 |
| | Antioxidant | AO-60 | 1 | 1 |

| | | | |
|---|---|---|---|
| Evaluation | Processability and properties | Adhesiveness | Filler |
| | | is different in | aggregated |
| | | each surface | |
| | Hardness (asker C) | 48 | 45 |
| | Thermal conductivity (W/m · K) | 1.65 | 1.28 |
| | Relative dielectric constant | 4.30 | 4.32 |
| | Flame retardancy (UL94 test) | V-2 | V-2 |
| | Moisture resistance | Poor | Poor |

It was confirmed that the sheets of Examples 1 to 6 had low relative dielectric constant and excellent thermal conductivity as shown in Tables 1 and 2. It was also confirmed that the sheets of Examples 1 to 6 had an appropriate hardness, and excellent flame retardancy, moisture resistance, and processability.

Comparative Example 1 is a case where the blended amount of the crystalline silica is too small. For the composition of Comparative Example 1, the composition was separated as described above, and thus a sheet could not be produced from the composition.

Comparative Example 2 is a case where the blended amount of the crystalline silica is larger than the blended amount of Comparative Example 1, but is too small. In Comparative Example 2, although a sheet could be produced from the composition, a small amount of separation occurred in the composition, and there was problem with processability.

Comparative Example 3 is a case where the blended amount of the crystalline silica is too large. The composition of Comparative Example 3 resulted in high viscosity of the composition, and low fluidity and hard as described above. Therefore, a sheet could not be produced using the composition.

Comparative Example 4 is a case where the blended amount of the aluminum hydroxide is too small. For the composition of Comparative Example 4, the composition was separated as described above, and thus a sheet could not be produced from the composition.

Comparative Example 5 is a case where the blended amount of the aluminum hydroxide is larger than the blended amount of Comparative Example 4, but is too small. In Comparative Example 5, although a sheet could be produced from the composition, a small amount of separation occurred in the composition, and there was problem with processability. For the sheet of Comparative Example 5, the result of flame retardancy was “V-2” and there was problem with flame retardancy.

Comparative Example 6 is a case where the blended amount of the aluminum hydroxide is too large. For Comparative Example 6, although a sheet could be produced from the composition, the fluidity of the composition was slightly low and there was problem with processability. The sheet of Comparative Example 6 resulted in excessive hardness.

Comparative Example 7 is a case where the blended amount of the polymerization initiator in the composition is too small. In Comparative Example 7, crosslinking reaction (polymerization reaction) was insufficient, and when a protective film attached to a sheet surface was peeled, a part of a material constituting the sheet was separated and remained attached to the protective film side.

Comparative Examples 8 and 9 are a case where the blended amount of the polymerization initiator in the composition is too large. It is presumed that, for the sheets of Comparative Examples 8 and 9, polymerization reaction of monomers and the like contained in the acrylic resin composition significantly proceeds, resulting in excessive hardness.

Comparative Examples 10 and 11 are a case where the blended amount of the plasticizer is too large. As shown in Example 5, the hardness of the sheet could be kept low by using a plasticizer, but when an excessive amount of the plasticizer was added, the sheet was deformed during peeling from the PET base material in the production of the sheet. Comparative Example 10 resulted in slight deformation, and Comparative Example 11 resulted in greater deformation than Comparative Example 10.

Comparative Example 12 is a case where no aluminum hydroxide is contained. It was confirmed that for the sheet of Comparative Example 12, flame retardancy was “V-2” and moisture was absorbed. The composition of Comparative Example 12 contained no aluminum hydroxide and thus the viscosity thereof was kept low, but crystalline silica and the like precipitated. Thus, the crystalline silica and the like were unevenly distributed on the lower surface side of the obtained sheet, resulting in occurrence of difference in adhesiveness between such a lower surface and an upper surface on the opposite side. It is presumed that, on the upper surface side, the amount of the resin component was large and thus adhesiveness was high, whereas on the lower surface side, the amount of the resin component was small and thus the adhesiveness became low.

Comparative Example 13 is a case where crystalline silica having a small average particle size is used. In the composition of Comparative Example 12, aggregation of the filler such as crystalline silica was observed. The sheet of Comparative Example 13 resulted in low thermal conductivity. It is presumed that the crystalline silica was not uniformly dispersed in the sheet due to its aggregation, and thus the heat transfer path due to crystalline silica was not sufficiently formed. It was also confirmed that for the sheet of Comparative Example 13, flame retardancy was “V-2” and moisture was absorbed.

1. A composition for a low dielectric thermally conductive material, comprising:
an acrylic resin composition containing an acrylic polymer formed by polymerizing one or two or more types of (meth)acrylates and one or two or more types of (meth)acrylates;
crystalline silica having an average particle size of 20 μm or greater;
a metal hydroxide having an average particle size of 15 μm or less;
a polyfunctional monomer; and
a polymerization initiator, wherein
per 100 parts by mass of the acrylic resin composition,
from 330 parts by mass to 440 parts by mass of the crystalline silica,
from 90 parts by mass to 190 parts by mass of the metal hydroxide,
from 0.01 parts by mass to 0.5 parts by mass of the polyfunctional monomer, and
from 0.6 parts by mass to 1.3 parts by mass of the polymerization initiator are blended.

2. The composition for a low dielectric thermally conductive material according to claim 1, wherein the metal hydroxide is composed of aluminum hydroxide.

3. A low dielectric thermally conductive material comprising a cured product of the composition for a low dielectric thermally conductive material according to claim 1.

4. The low dielectric thermally conductive material according to claim 3, wherein an asker C hardness is 50 or less, a relative dielectric constant is 5.0 or less, and a thermal conductivity is 1.4 W/m·K or greater.

5. The low dielectric thermally conductive material according to claim 4, wherein the low dielectric thermally conductive material is composed of the cured product of the composition for a low dielectric thermally conductive material formed in a sheet shape.

6. The low dielectric thermally conductive material according to claim 3, wherein the low dielectric thermally conductive material is composed of the cured product of the composition for a low dielectric thermally conductive material formed in a sheet shape.

7. A low dielectric thermally conductive material comprising a cured product of the composition for a low dielectric thermally conductive material according to claim 2.

8. The low dielectric thermally conductive material according to claim 7, wherein an asker C hardness is 50 or less, a relative dielectric constant is 5.0 or less, and a thermal conductivity is 1.4 W/m·K or greater.

9. The low dielectric thermally conductive material according to claim 8, wherein the low dielectric thermally conductive material is composed of the cured product of the composition for a low dielectric thermally conductive material formed in a sheet shape.

10. The low dielectric thermally conductive material according to claim 7, wherein the low dielectric thermally conductive material is composed of the cured product of the composition for a low dielectric thermally conductive material formed in a sheet shape.
